(19) United States
(12) Patent Application Publication
(10) Pub. No.: US 2026/0032803 A1
(43) Pub. Date: Jan. 29, 2026

(54) HEAT DISSIPATION MEMBER AND ELECTRONIC DEVICE COMPRISING SAME

(71) Applicant: Samsung Electronics Co., Ltd., Suwon-si (KR)

(72) Inventors: Jonghyun LIM, Suwon-si (KR); Haein CHUNG, Suwon-si (KR); Hongki MOON, Suwon-si (KR); Hui JEONG, Suwon-si (KR)

(21) Appl. No.: 19/349,108

(22) Filed: Oct. 3, 2025

Related U.S. Application Data
(63) Continuation of application No. PCT/KR2024/004141, filed on Apr. 1, 2024.

(30) Foreign Application Priority Data
May 30, 2023 (KR) 10-2023-0069433
Apr. 6, 2023 (KR) 10-2023-0045560

(51) Int. Cl. H05K 1/02; G06F 1/20

(52) U.S. Cl. CPC H05K 1/0203; G06F 1/20; H05K 2201/064

(57) ABSTRACT

An electronic device comprising a heat dissipation member is provided. The electronic device includes a substrate portion including a heat source disposed on the substrate, and a heat dissipation member placed in contact with the heat source and configured to dissipate heat of the heating source, wherein the heat dissipation member includes a heat absorbing portion including a vapor chamber and configured to absorb the heat from the heat source, a heat radiating portion configured to release the heat absorbed by the heat absorbing portion, and a heat pipe bonded to the vapor chamber and configured to form a thermal circuit connecting the heat absorbing portion and the heat radiating portion.

### CROSS-REFERENCE TO RELATED APPLICATIONS

This application is a continuation application, claiming priority under 35 U.S.C. § 365(c), of an international application no. PCT/KR2024/004141, filed on April 1, 2024, which is based on and claims the benefit of a Korean patent application number 10-2023-0045560, filed on April 6, 2023, in the Korean intellectual property office, and of a Korean patent application number 10-2023-0069433, filed on may 30, 2023, in the Korean intellectual property office, the disclosure of each of which is incorporated by reference herein in its entirety.

### BACKGROUND

### Field

The disclosure relates to an electronic device. More particularly, the disclosure relates to an electronic device including a heat dissipation member.

### Description of Related Art

An electronic device includes various heat sources such as a processor, a power device, a power management integrated circuit (PMIC), and a battery. Heat generated from the heat sources increases the internal temperature of the electronic device, and the increased temperature may interfere with the operation of components of the electronic device or damage the components. Accordingly, means for smoothly releasing heat generated inside the electronic device to the outside are required.

The electronic device may include various heat dissipation means. The electronic device may include a vent configured to release heat generated inside the electronic device to the outside of the electronic device, and a blowing means configured to supply cooling air to the vent. The electronic device may further include a heat dissipation member configured to transfer heat generated from the heat sources to the vent.

The above information is presented as background information only to assist with an understanding the disclosure. No determination has been made, and no assertion is made, as to whether any of the above might be applicable as prior art with regard to the disclosure.

### SUMMARY

As a heat dissipation member for transferring heat of a heat source of an electronic device, a phase-change heat exchanger having a phase-change material as a working fluid therein may be used. The phase-change heat exchanger may be, for example, a heat pipe or a vapor chamber. The heat pipe is relatively inexpensive and is easy to form a complex heat transfer path having bent or curved sections, but since the heat pipe transfers heat one-dimensionally along a length direction, heat transfer performance deteriorates as the heat transfer path becomes longer. In addition, although the vapor chamber has high heat transfer performance due to two-dimensional heat transfer on a plane, the vapor chamber has a relatively high cost, and when manufactured to have a bent heat transfer path, a chamfer ratio of a plate is reduced, thereby further increasing the cost.

Aspects of the disclosure are to address at least the above-mentioned problems and/or disadvantages and to provide at least the advantages described below. Accordingly, an aspect of the disclosure is to provide an electronic device having a heat dissipation member that is relatively inexpensive while having a bent heat transfer path and has high heat transfer performance.

Additional aspects will be set forth in part in the description which follows and, in part, will be apparent from the description, or may be learned by practice of the presented embodiments.

In accordance with an aspect of the disclosure, an electronic device is provided. The electronic device includes a substrate including a heat source disposed on the substrate, and a heat dissipation member placed in contact with the heat source and configured to dissipate heat of the heat source wherein the heat dissipation member includes a heat absorbing portion including a vapor chamber and configured to absorb heat from the heat source, a heat radiating portion configured to release the heat absorbed by the heat absorbing portion, and a heat pipe bonded to the vapor chamber and configured to form a thermal circuit connecting the heat absorbing portion and the heat radiating portion.

In accordance with another aspect of the disclosure, a heat dissipation member of an electronic device having a heat source is provided. The heat dissipation member includes a heat absorbing portion including a vapor chamber and configured to absorb heat from the heat source, a heat radiating portion configured to release the heat absorbed by the heat absorbing portion, and a heat pipe bonded to the vapor chamber and configured to form a thermal circuit connecting the heat absorbing portion and the heat radiating portion.

According to various embodiments disclosed herein, a heat dissipation member having high heat transfer performance even in a bent heat transfer path is provided at a relatively low cost by absorbing heat of a heat source through a vapor chamber and transferring the heat to a heat radiating portion through a heat pipe bonded to the vapor chamber.

Other aspects, advantages, and salient features of the disclosure will become apparent to those skilled in the art from the following detailed description, which, taken in conjunction with the annexed drawings, discloses various embodiments of the disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a block diagram of an electronic device in a network environment according to an embodiment of the disclosure;

FIG. 2 is a perspective view of an electronic device according to an embodiment of the disclosure;

FIG. 3A is a plan view of an internal configuration of an electronic device according to an embodiment of the disclosure;

FIG. 3B is a plan view of a heat dissipation member according to an embodiment of the disclosure;

FIG. 3C is a cross-sectional view of the heat dissipation member according to an embodiment of the disclosure;

FIG. 3D is an enlarged side view of the heat dissipation member according to an embodiment of the disclosure;

FIG. 4A is a schematic cross-sectional view of a heat dissipation member according to an embodiment of the disclosure;

FIG. 4B is a schematic cross-sectional view of the heat dissipation member according to an embodiment of the disclosure;

FIG. 5A is a perspective view illustrating a vapor chamber of a heat dissipation member according to an embodiment of the disclosure;

FIG. 5B is a cross-sectional view illustrating the vapor chamber of the heat dissipation member according to an embodiment of the disclosure;

FIG. 5C is a perspective view illustrating the vapor chamber and the heat pipe according to an embodiment of the disclosure;

FIG. 5D is a cross-sectional view illustrating the vapor chamber and the heat pipe according to an embodiment of the disclosure;

FIG. 5E is an enlarged view illustrating the vapor chamber and the heat pipe according to an embodiment of the disclosure; and

FIG. 6 is a graph illustrating temperatures of heat sources during operation of electronic devices according to an embodiment of the disclosure.

Throughout the drawings, it should be noted that like reference numbers are used to depict the same or similar elements, features, and structures.

### DETAILED DESCRIPTION

The following description with reference to the accompanying drawings is provided to assist in a comprehensive understanding of various embodiments of the disclosure as defined by the claims and their equivalents. It includes various specific details to assist in that understanding but these are to be regarded as merely exemplary. Accordingly, those of ordinary skill in the art will recognize that various changes and modifications of the various embodiments described herein can be made without departing from the scope and spirit of the disclosure. In addition, descriptions of well-known functions and constructions may be omitted for clarity and conciseness.

The terms and words used in the following description and claims are not limited to the bibliographical meanings, but, are merely used by the inventor to enable a clear and consistent understanding of the disclosure. Accordingly, it should be apparent to those skilled in the art that the following description of various embodiments of the disclosure is provided for illustration purpose only and not for the purpose of limiting the disclosure as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces.

As used herein, each of such phrases as "A or B," "at least one of A and B," “at least one of A or B,” "A, B, or C," "at least one of A, B, and C," and “at least one of A, B, or C” may include all possible combinations of the items enumerated together in a corresponding one of the phrases. Such terms as "a first," "a second," “the first,” and "the second" may be used to simply distinguish a corresponding element from another, and does not limit the elements in other aspect (e.g., importance or order). If an element (e.g., a first element) is referred to, with or without the term “operatively” or “communicatively”, as “coupled with/to” or “connected with/to” another element (e.g., a second element), it means that the element may be coupled/connected with/to the other element directly (e.g., wiredly), wirelessly, or via a third element.

It should be appreciated that the blocks in each flowchart and combinations of the flowcharts may be performed by one or more computer programs which include instructions. The entirety of the one or more computer programs may be stored in a single memory device or the one or more computer programs may be divided with different portions stored in different multiple memory devices.

Any of the functions or operations described herein can be processed by one processor or a combination of processors. The one processor or the combination of processors is circuitry performing processing and includes circuitry like an application processor (AP, e.g. a central processing unit (CPU)), a communication processor (CP, e.g., a modem), a graphics processing unit (GPU), a neural processing unit (NPU) (e.g., an artificial intelligence (AI) chip), a wireless fidelity (Wi-Fi) chip, a Bluetooth^{®} chip, a global positioning system (GPS) chip, a near field communication (NFC) chip, connectivity chips, a sensor controller, a touch controller, a finger-print sensor controller, a display driver integrated circuit (IC), an audio CODEC chip, a universal serial bus (USB) controller, a camera controller, an image processing IC, a microprocessor unit (MPU), a system on chip (SoC), an IC, or the like.

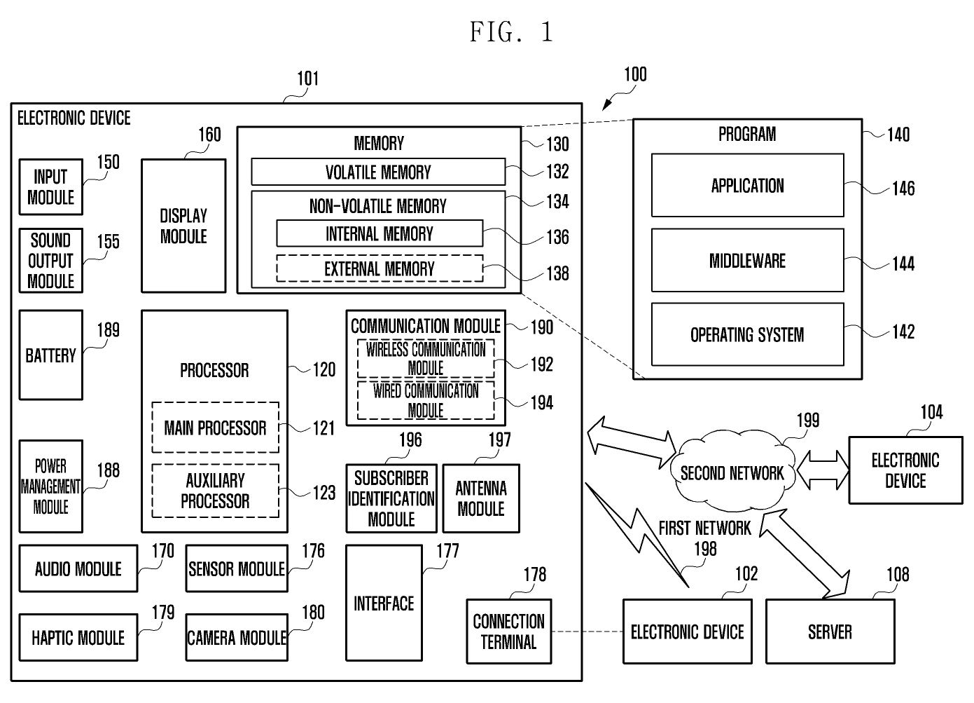

FIG. 1 is a block diagram illustrating an electronic device 101 in a network environment 100 according to an embodiment of the disclosure.

Referring to FIG. 1, the electronic device 101 in the network environment 100 may communicate with an electronic device 102 via a first network 198 (e.g., a short-range wireless communication network), or at least one of an electronic device 104 or a server 108 via a second network 199 (e.g., a long-range wireless communication network). According to an embodiment, the electronic device 101 may communicate with the electronic device 104 via the server 108. According to an embodiment, the electronic device 101 may include a processor 120, memory 130, an input module 150, a sound output module 155, a display module 160, an audio module 170, a sensor module 176, an interface 177, a connecting terminal 178, a haptic module 179, a camera module 180, a power management module 188, a battery 189, a communication module 190, a subscriber identification module (SIM) 196, or an antenna module 197. In some embodiments, at least one of the components (e.g., the connecting terminal 178) may be omitted from the electronic device 101, or one or more other components may be added in the electronic device 101. In some embodiments, some of the components (e.g., the sensor module 176, the camera module 180, or the antenna module 197) may be implemented as a single component (e.g., the display module 160).

The processor 120 may execute, for example, software (e.g., a program 140) to control at least one other component (e.g., a hardware or software component) of the electronic device 101 coupled with the processor 120, and may perform various data processing or computation. According to one embodiment, as at least part of the data processing or computation, the processor 120 may store a command or data received from another component (e.g., the sensor module 176 or the communication module 190) in volatile memory 132, process the command or the data stored in the volatile memory 132, and store resulting data in non-volatile memory 134. According to an embodiment, the processor 120 may include a main processor 121 (e.g., a central processing unit (CPU) or an application processor (AP)), or an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. For example, when the electronic device 101 includes the main processor 121 and the auxiliary processor 123, the auxiliary processor 123 may be adapted to consume less power than the main processor 121, or to be specific to a specified function. The auxiliary processor 123 may be implemented as separate from, or as part of the main processor 121.

The auxiliary processor 123 may control at least some of functions or states related to at least one component (e.g., the display module 160, the sensor module 176, or the communication module 190) among the components of the electronic device 101, instead of the main processor 121 while the main processor 121 is in an inactive (e.g., sleep) state, or together with the main processor 121 while the main processor 121 is in an active state (e.g., executing an application). According to an embodiment, the auxiliary processor 123 (e.g., an image signal processor or a communication processor) may be implemented as part of another component (e.g., the camera module 180 or the communication module 190) functionally related to the auxiliary processor 123. According to an embodiment, the auxiliary processor 123 (e.g., the neural processing unit) may include a hardware structure specified for artificial intelligence model processing. An artificial intelligence model may be generated by machine learning. Such learning may be performed, e.g., by the electronic device 101 where the artificial intelligence is performed or via a separate server (e.g., the server 108). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 130 may store various data used by at least one component (e.g., the processor 120 or the sensor module 176) of the electronic device 101. The various data may include, for example, software (e.g., the program 140) and input data or output data for a command related thereto. The memory 130 may include the volatile memory 132 or the non-volatile memory 134.

The program 140 may be stored in the memory 130 as software, and may include, for example, an operating system (OS) 142, middleware 144, or an application 146.

The input module 150 may receive a command or data to be used by another component (e.g., the processor 120) of the electronic device 101, from the outside (e.g., a user) of the electronic device 101. The input module 150 may include, for example, a microphone, a mouse, a keyboard, a key (e.g., a button), or a digital pen (e.g., a stylus pen).

The sound output module 155 may output sound signals to the outside of the electronic device 101. The sound output module 155 may include, for example, a speaker or a receiver. The speaker may be used for general purposes, such as playing multimedia or playing record. The receiver may be used for receiving incoming calls. According to an embodiment, the receiver may be implemented as separate from, or as part of the speaker.

The display module 160 may visually provide information to the outside (e.g., a user) of the electronic device 101. The display module 160 may include, for example, a display, a hologram device, or a projector and control circuitry to control a corresponding one of the display, hologram device, and projector. According to an embodiment, the display module 160 may include a touch sensor adapted to detect a touch, or a pressure sensor adapted to measure the intensity of force incurred by the touch.

The audio module 170 may convert a sound into an electrical signal and vice versa. According to an embodiment, the audio module 170 may obtain the sound via the input module 150, or output the sound via the sound output module 155 or a headphone of an external electronic device (e.g., an electronic device 102) directly (e.g., wiredly) or wirelessly coupled with the electronic device 101.

The sensor module 176 may detect an operational state (e.g., power or temperature) of the electronic device 101 or an environmental state (e.g., a state of a user) external to the electronic device 101, and then generate an electrical signal or data value corresponding to the detected state. According to an embodiment, the sensor module 176 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly (e.g., wiredly) or wirelessly. According to an embodiment, the interface 177 may include, for example, a high definition multimedia interface (HDMI), a universal serial bus (USB) interface, a secure digital (SD) card interface, or an audio interface.

A connecting terminal 178 may include a connector via which the electronic device 101 may be physically connected with the external electronic device (e.g., the electronic device 102). According to an embodiment, the connecting terminal 178 may include, for example, a HDMI connector, a USB connector, a SD card connector, or an audio connector (e.g., a headphone connector).

The haptic module 179 may convert an electrical signal into a mechanical stimulus (e.g., a vibration or a movement) or electrical stimulus which may be recognized by a user via his tactile sensation or kinesthetic sensation. According to an embodiment, the haptic module 179 may include, for example, a motor, a piezoelectric element, or an electric stimulator.

The camera module 180 may capture a still image or moving images. According to an embodiment, the camera module 180 may include one or more lenses, image sensors, image signal processors, or flashes.

The power management module 188 may manage power supplied to the electronic device 101. According to one embodiment, the power management module 188 may be implemented as at least part of, for example, a power management integrated circuit (PMIC).

The battery 189 may supply power to at least one component of the electronic device 101. According to an embodiment, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more communication processors that are operable independently from the processor 120 (e.g., the application processor (AP)) and supports a direct (e.g., wired) communication or a wireless communication. According to an embodiment, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). A corresponding one of these communication modules may communicate with the external electronic device via the first network 198 (e.g., a short-range communication network, such as Bluetooth^{TM}, wireless-fidelity (Wi-Fi) direct, or infrared data association (IrDA)) or the second network 199 (e.g., a long-range communication network, such as a legacy cellular network, a fifth generation (5G) network, a next-generation communication network, the Internet, or a computer network (e.g., LAN or wide area network (WAN)). These various types of communication modules may be implemented as a single component (e.g., a single chip), or may be implemented as multi components (e.g., multi chips) separate from each other. The wireless communication module 192 may identify and authenticate the electronic device 101 in a communication network, such as the first network 198 or the second network 199, using subscriber information (e.g., international mobile subscriber identity (IMSI)) stored in the subscriber identification module 196.

The wireless communication module 192 may support a 5G network, after a fourth generation (4G) network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 192 may support a high-frequency band (e.g., the millimeter wave (mmWave) band) to achieve, e.g., a high data transmission rate. The wireless communication module 192 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 192 may support various requirements specified in the electronic device 101, an external electronic device (e.g., the electronic device 104), or a network system (e.g., the second network 199). According to an embodiment, the wireless communication module 192 may support a peak data rate (e.g., 20Gbps or more) for implementing eMBB, loss coverage (e.g., 164dB or less) for implementing mMTC, or U-plane latency (e.g., 0.5ms or less for each of downlink (DL) and uplink (UL), or a round trip of 1ms or less) for implementing URLLC.

The antenna module 197 may transmit or receive a signal or power to or from the outside (e.g., the external electronic device) of the electronic device 101. According to an embodiment, the antenna module 197 may include an antenna including a radiating element composed of a conductive material or a conductive pattern formed in or on a substrate (e.g., a printed circuit board (PCB)). According to an embodiment, the antenna module 197 may include a plurality of antennas (e.g., array antennas). In such a case, at least one antenna appropriate for a communication scheme used in the communication network, such as the first network 198 or the second network 199, may be selected, for example, by the communication module 190 (e.g., the wireless communication module 192) from the plurality of antennas. The signal or the power may then be transmitted or received between the communication module 190 and the external electronic device via the selected at least one antenna. According to an embodiment, another component (e.g., a radio frequency integrated circuit (RFIC)) other than the radiating element may be additionally formed as part of the antenna module 197.

According to various embodiments, the antenna module 197 may form a mmWave antenna module. According to an embodiment, the mmWave antenna module may include a printed circuit board, a RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 101 and the external electronic device 104 via the server 108 coupled with the second network 199. Each of the electronic devices 102 or 104 may be a device of a same type as, or a different type, from the electronic device 101. According to an embodiment, all or some of operations to be executed at the electronic device 101 may be executed at one or more of the external electronic devices 102, 104, or server 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may provide ultra low-latency services using, e.g., distributed computing or mobile edge computing. In another embodiment, the external electronic device 104 may include an internet-of-things (IoT) device. The server 108 may be an intelligent server using machine learning and/or a neural network. According to an embodiment, the external electronic device 104 or the server 108 may be included in the second network 199. The electronic device 101 may be applied to intelligent services (e.g., smart home, smart city, smart car, or healthcare) based on 5G communication technology or IoT-related technology.

The electronic device according to various embodiments may be one of various types of electronic devices. The electronic devices may include, for example, a portable communication device (e.g., a smartphone), a computer device, a portable multimedia device, a portable medical device, a camera, a wearable device, or a home appliance. According to an embodiment of the disclosure, the electronic devices are not limited to those described above.

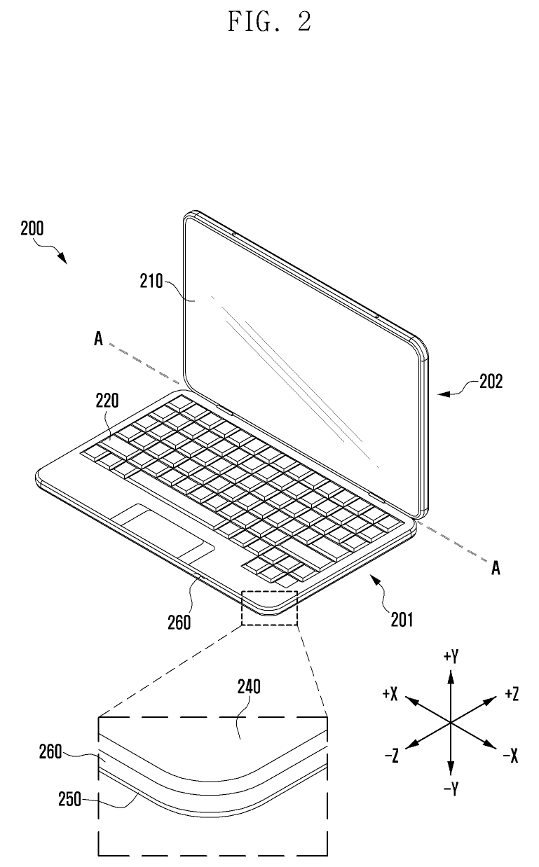

FIG. 2 is a perspective view of an electronic device according to an embodiment of the disclosure.

According to embodiments of the disclosure, an electronic device 200 (e.g., the electronic device 101 of FIG. 1) may include, as an example, a laptop-type electronic device 200 as illustrated in FIG. 2. In another example, the electronic device 200 may take a form factor such as a tablet computer and/or a convertible tablet-laptop. The electronic device 200 may include one or more housings 201 and 202 to accommodate various components therein and to protect the components. For example, as illustrated in FIG. 2, the electronic device 200 may include a first housing 201 and a second housing 202 coupled to each other so as to be foldable with respect to each other. The first housing 201 and the second housing 202 may be rotatable with respect to each other about a folding axis (e.g., axis A-A illustrated in FIG. 2). In some embodiments, the electronic device 200 may be foldable such that a physical keyboard 220 disposed in the first housing 201 (e.g., the input module 150 of FIG. 1) and a display module 210 disposed in the second housing 202 (e.g., the display module 160 of FIG. 1) face each other.

In an embodiment, the first housing 201 and the second housing 202 may be disposed on opposite sides about the folding axis (e.g., axis A-A illustrated in FIG. 2) and may have an overall symmetrical shape with respect to the folding axis. In another embodiment, the first housing 201 and the second housing 202 may have an asymmetrical shape with respect to the folding axis. An angle or distance formed between the first housing 201 and the second housing 202 may vary depending on whether the electronic device 200 is in an unfolded state, a folded state, or an intermediate state.

According to various embodiments, an exterior of a first housing 201 may include a first cover 240, a second cover 250, and a frame 260 surrounding a space between the first cover 240 and the second cover 250. In some embodiments, the frame 260 may be integrally formed with at least one of the first cover 240 and the second cover 250. In another embodiment, the frame 260 may be separately manufactured from the first cover 240 and the second cover 250 and may be coupled to at least one of the first cover 240 and the second cover 250. For example, the first cover 240, the second cover 250, and the frame 260 may be connected to each other in a plurality of divided portions in various manners (e.g., bonding through an adhesive, bonding through welding, or bolt coupling). Similarly, a second housing 202 may have a configuration that the same as or a similar to that of the first housing 201.

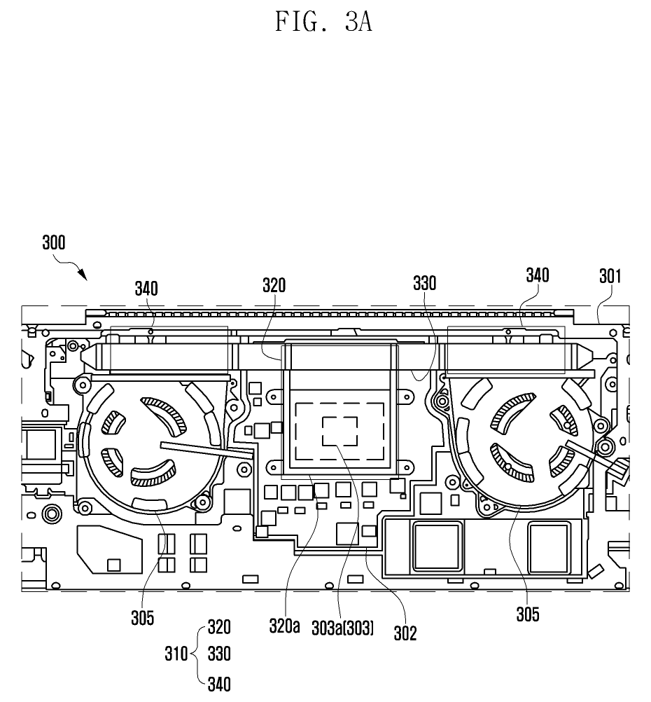

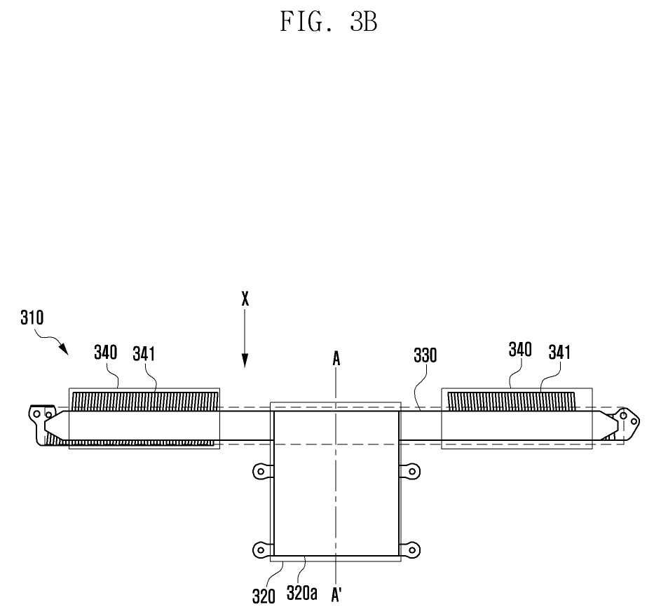

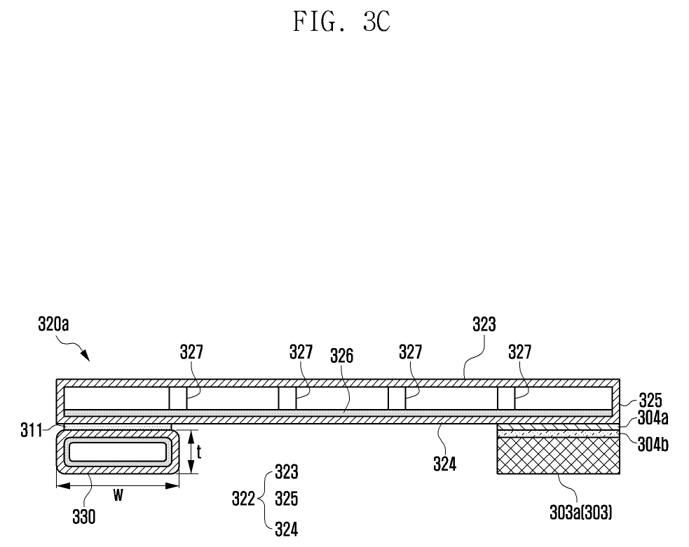

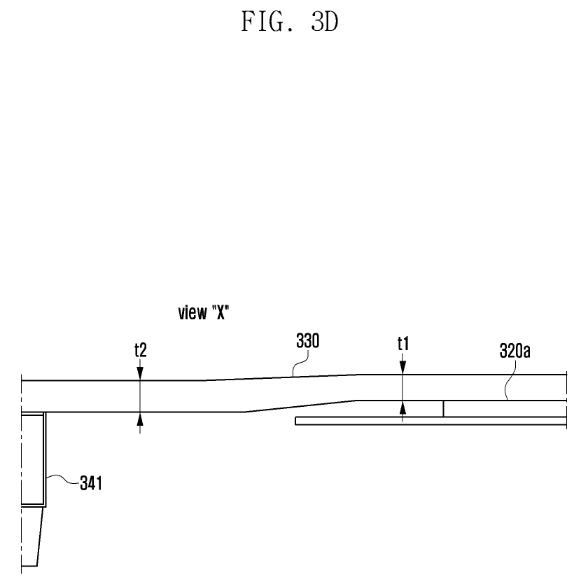

FIG. 3A is a plan view of an internal configuration of an electronic device 300 according to an embodiment of the disclosure.

FIG. 3B is a plan view of a heat dissipation member 310 according to an embodiment of the disclosure.

FIG. 3C is a cross-sectional view of the heat dissipation member 310 according to an embodiment of the disclosure.

FIG. 3D is an enlarged side view of the heat dissipation member 310 according to an embodiment of the disclosure.

The cross-section of FIG. 3C is a cross-section taken along line A-A’ of FIG. 3B, and FIG. 3D is an enlarged side view as viewed in direction X of FIG. 3B.

Referring to FIG. 3A, an electronic device 300 (e.g., the electronic device 101 of FIG. 1, or the electronic device 200 of FIG. 2) may include a housing 301 (e.g., the first housing 201 of FIG. 2), and a substrate 302 may be disposed in the housing 301. The substrate 302 may be a member where various electrical components, such as a processor 303a (e.g., the processor 120 of FIG. 1), are disposed and electrically connected. Since components such as the processor 303a disposed on the substrate 302 generate heat during operation, they may be referred to as a heat source 303.

A heat dissipation member 310 may be disposed on the heat source 303 of the substrate 302. For example, the heat dissipation member 310 may be disposed to be in contact with one surface of the processor 303a. The heat dissipation member 310 may include a heat absorbing portion 320 configured to absorb heat of the heat source 303 and a heat radiating portion 340 configured to release the heat absorbed by the heat absorbing portion 320. A detailed configuration of the heat dissipation member 310 will be described later.

In various embodiments, the electronic device 300 may include a blower 305.

The blower 305 may be a device configured to discharge heat released through the heat dissipation member 310 to the outside of the electronic device 300 by flowing air to the heat radiating portion 340 of the heat dissipation member 310. The blower 305 may include various types of fans such as an axial fan, a centrifugal fan, and/or a toroidal fan.

Referring to FIGS. 3B and 3C, the heat dissipation member 310 may include a heat absorbing portion 320, a heat radiating portion 340, and a heat pipe 330. The heat pipe 330 may be a member configured to transfer heat of the heat source 303 absorbed in the heat absorbing portion 320 to the heat radiating portion 340.

In various embodiments, the heat absorbing portion 320 may include a vapor chamber 320a. The vapor chamber 320a may be a member having an outer wall 322 and an inner space surrounded by the outer wall, including a phase change material (PCM) positioned in the inner space, and configured to transfer heat two-dimensionally in a surface direction of the vapor chamber 320a through vaporization, transport, and condensation of the phase change material. For example, the outer wall 322 of the vapor chamber 320a may include a first plate 323, a side wall 325 formed along an outer periphery of the first plate 323, and a second plate 324 positioned in parallel with the first plate 323 while being in contact with the side wall 325, and the inner space may be defined by the first plate 323, the second plate 324, and the side wall 325. The side wall 325 may be a separate member or may be a member integrally formed with the second plate 324 by a method such as pressing. In various embodiments, the vapor chamber 320a may include a wick 326 positioned in the inner space and configured to promote transport of liquid phase change material, and a support member 327 (e.g., a filler) configured to support the first plate 323 with respect to the second plate 324. The vapor chamber 320a may include a material having excellent thermal conductivity, such as copper or SUS, for superior heat transfer.

In various embodiments, a portion of the vapor chamber 320a may be in contact with a heat source 303 such as the processor 303a. For example, a portion of the second plate 324 may be in contact with the processor 303a. The processor 303a and the vapor chamber 320a may be in direct contact, or may be in indirect contact with each other with a member such as a heat spreader 304a (e.g., a Cu plate) and/or a thermal interface material (TIM) 304b interposed therebetween. In an example, a stacking order of the vapor chamber 320a and the processor 303a may be in the order of the vapor chamber 320a, the heat spreader 304a, the thermal interface material 304b, and the processor 303a, but the disclosure is not limited thereto.

The heat pipe 330 may be a member having a tubular outer wall 322 including a phase change material therein. The heat pipe 330 may be a member configured to transfer heat one-dimensionally in a length direction thereof through vaporization, flow, and condensation of the phase change material. The heat pipe 330 may include a material having excellent thermal conductivity, such as copper, for superior heat transfer. In various embodiments, the heat pipe 330 may have a cross-sectional shape in which a thickness t is smaller than a width w. For example, such a cross-sectional shape of the heat pipe 330 may be processed into an elliptical shape, a stadium shape, or a similar cross-sectional shape by deforming a circular or similar cross-section of the heat pipe 330 using means such as pressing.

In various embodiments, the heat pipe 330 may be bonded to the vapor chamber 320a. The bonding may be achieved by technical means capable of bonding metal to metal without a gap, such as welding, soldering, and/or brazing. Accordingly, heat absorbed by the vapor chamber 320a may be effectively transferred to the heat pipe 330. As an example, the vapor chamber 320a and the heat pipe 330 may be surface-bonded by a solder layer 311. Details of a bonding structure of the vapor chamber 320a and the heat pipe 330 by the solder layer 311 will be described later.

The heat radiating portion 340 may be a portion configured to have a large surface area to release heat transferred through the heat pipe 330. For example, the heat radiating portion 340 may include a member such as a cooling fin 341 configured to increase a heat release area while being in contact with the heat pipe 330.

During operation of the heat dissipation member 310, heat absorbed by the vapor chamber 320a from the heat source 303 may be transferred to the heat pipe 330 bonded to the vapor chamber 320a, and the heat pipe 330 may transfer the heat received from the vapor chamber 320a to the heat radiating portion 340, so that the heat of the heat source 303 may be released to the outside of the electronic device 300. The heat dissipation member 310 of the disclosure may achieve relatively excellent heat transfer performance by using the vapor chamber 320a in the heat absorbing portion 320, which is a high-temperature area, and may eliminate or reduce cost increase caused by chamfering loss of the vapor chamber 320a even when a bent or curved section is present in a heat transfer path by connecting the heat absorbing portion 320 and the heat radiating portion 340 using the heat pipe 330, which is easy to bend.

Referring to FIG. 3D, a thickness of a portion of the heat pipe 330 may be reduced compared to another portion. For example, the heat pipe 330 may have a thickness t1 in a region overlapping the vapor chamber 320a that is smaller than a thickness t2 in another region. Accordingly, an increase in thickness due to the overlap of the heat pipe 330 and the vapor chamber 320a may be at least partially compensated. In some embodiments, the heat pipe 330 may be additionally pressed in a region to overlap the vapor chamber 320a so that the thickness t2 is reduced. Through such processing, the contact area between the heat pipe 330 and the vapor chamber 320a may be increased, and thus, even if heat transfer performance of the heat pipe 330 is degraded due to the reduction of the thickness of the heat pipe 330, the degradation may be at least partially compensated by an increase in a heat transfer area resulting from the increase in the contact area between the heat pipe 330 and the vapor chamber 320a.

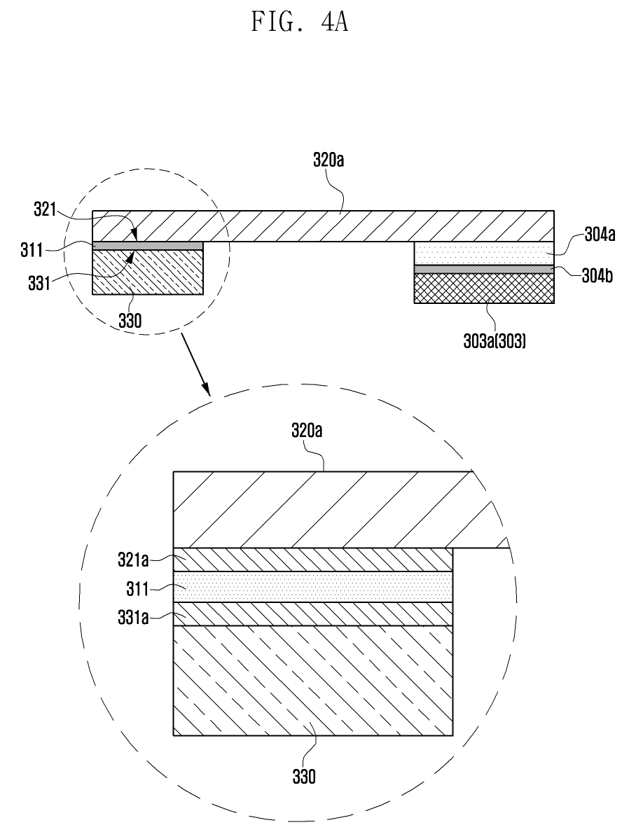

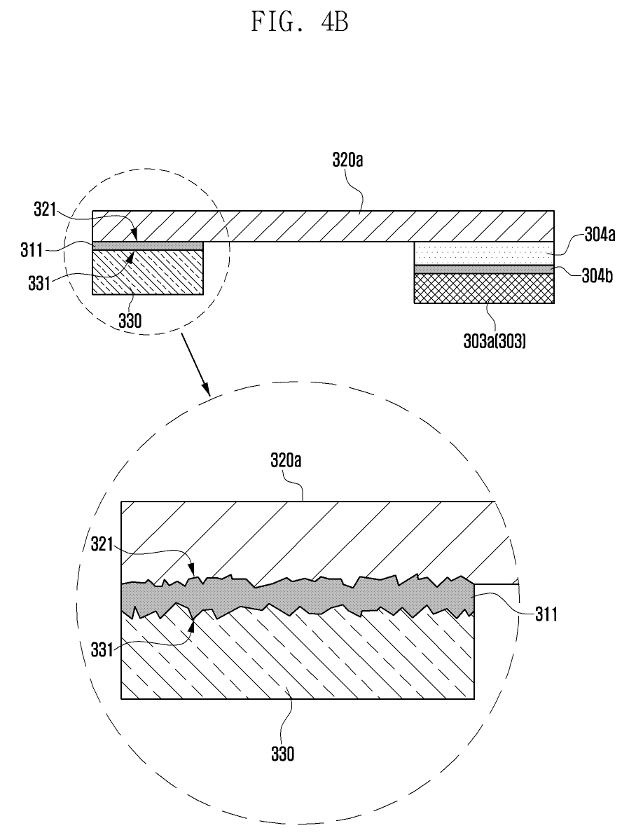

FIG. 4A is a schematic cross-sectional view of a heat dissipation member 310 according to an embodiment of the disclosure.

FIG. 4B is a schematic cross-sectional view of the heat dissipation member 310 according to an embodiment of the disclosure.

Referring to FIG. 4B, the vapor chamber 320a may have a first surface 321 that is in contact with the heat pipe 330, and the heat pipe 330 may have a second surface 331 that is in contact with the vapor chamber 320a. In various embodiments, a solder layer 311 may be positioned between the first surface 321 and the second surface 331 to bond the first surface 321 and the second surface 331.

In various embodiments, at least one of the first surface 321 and the second surface 331 may include a surface modification layer. The surface modification layer may be a layer configured to improve solder bonding and thermal conduction between the heat pipe 330 and the vapor chamber 320a. For example, a first plating layer 321a may be formed on the first surface 321. A second plating layer 331a may be formed on the second surface 331. The first and second plating layers 321a and 331a may be made of a metal or an alloy having wettability to a molten solder alloy improved compared to a base material (e.g., copper). For example, a contact angle of the molten solder alloy with respect to the first and second plating layers 321a and 331a may be a smaller angle (e.g., about 15 degrees or less) compared to a contact angle between the base material and a molten solder alloy (e.g., about 20 degrees, which is a contact angle between copper and a molten tin-based solder alloy). The first and second plating layers 321a and 331a may be made of a metal or an alloy including, for example, gold, nickel, silver, and/or tin. In addition, various technical means for reducing surface energy with respect to a molten solder alloy of the first surface 321 and/or the second surface 331 are included in the scope of the disclosure.

Referring to FIG. 4B, in various embodiments, at least one of the first surface 321 and the second surface 331 may be roughened. The roughening may be performed by a physical method (e.g., sand blasting and/or scratching) and/or a chemical method such as etching.

The first surface 321 and/or the second surface 331 may have increased wettability to a molten solder alloy by the above-described surface modification layer or roughening, and thus, the molten solder may easily penetrate and fill a gap between the first surface 321 and the second surface 331. Accordingly, a solder layer 311 formed by solidification of the molten solder may be attached to the first surface 321 and/or the second surface 331 with no air gap or with a reduced air gap. Therefore, generation of an air gap at a bonding portion between the heat pipe 330 and the vapor chamber 320a, which would increase thermal resistance, may be prevented or further reduced.

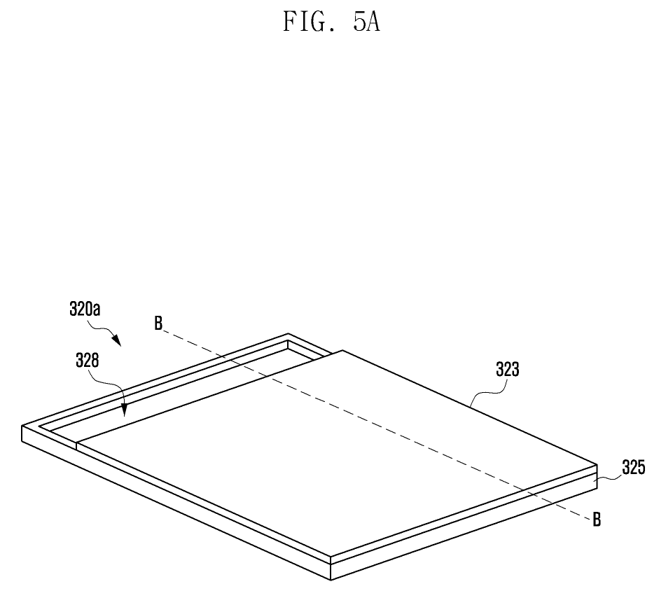

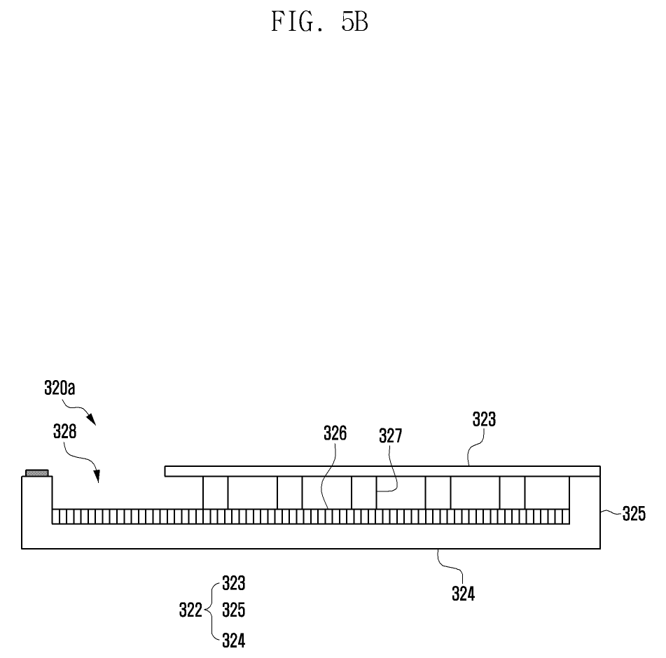

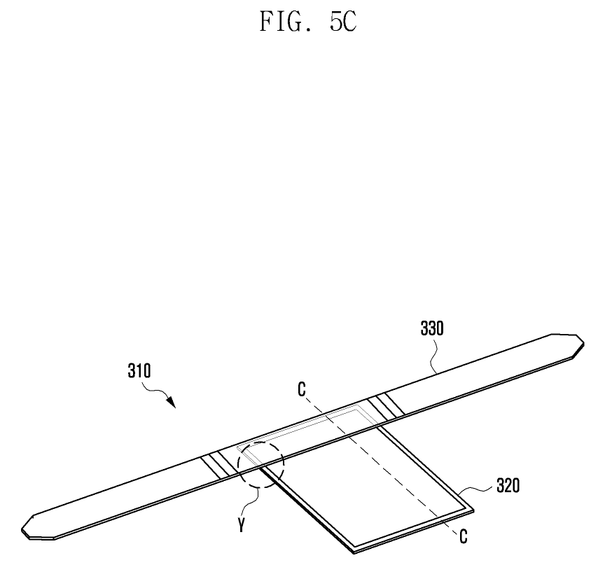

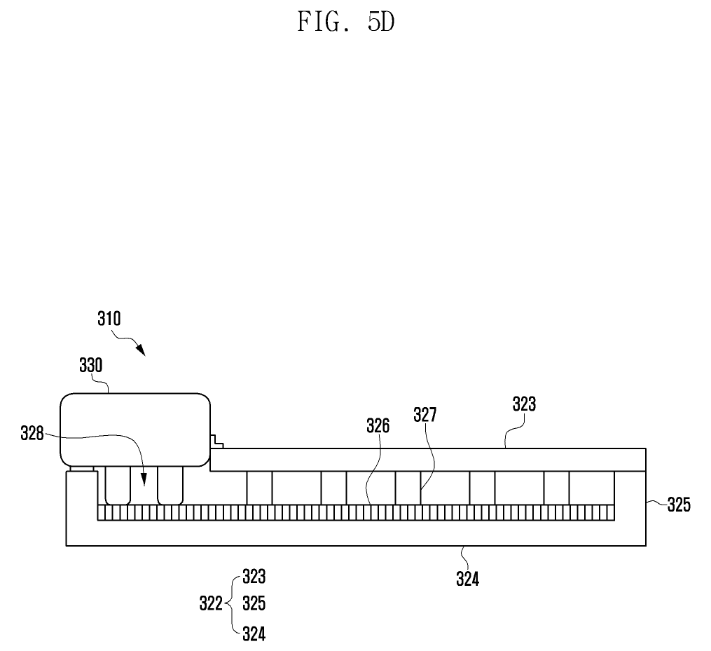

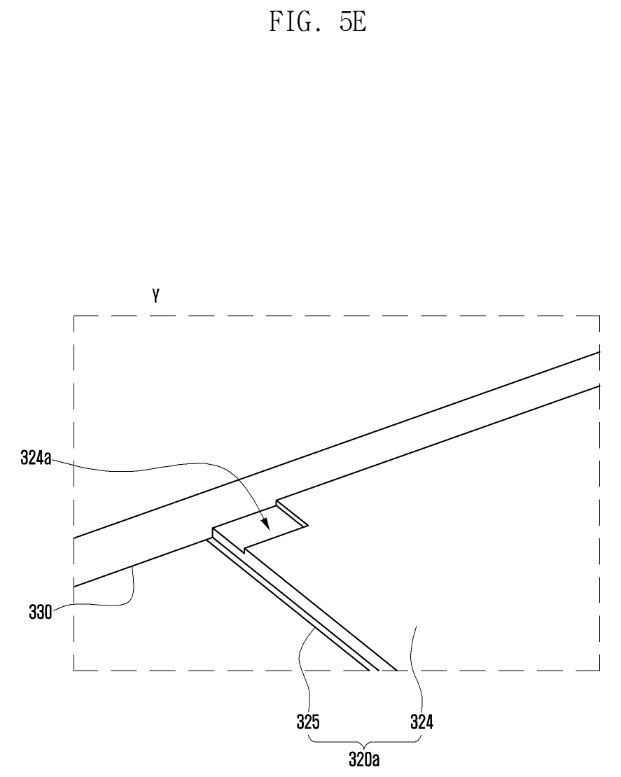

FIG. 5A is a perspective view illustrating a vapor chamber 320a of a heat dissipation member 310 according to an embodiment of the disclosure.

FIG. 5B is a cross-sectional view illustrating the vapor chamber 320a of the heat dissipation member 310 according to an embodiment of the disclosure.

FIG. 5C is a perspective view illustrating the vapor chamber 320a and the heat pipe 330 according to an embodiment of the disclosure.

FIG. 5D is a cross-sectional view illustrating the vapor chamber 320a and the heat pipe 330 according to an embodiment of the disclosure.

FIG. 5E is an enlarged view illustrating the vapor chamber 320a and the heat pipe 330 according to an embodiment of the disclosure.

FIG. 5B illustrates a cross-section taken along line B-B of FIG. 5A, FIG. 5D illustrates a cross-section taken along line C-C of FIG. 5C, and FIG. 5E is an enlarged view of region Y of FIG. 5C.

Referring to FIGS. 5A and 5B, the vapor chamber 320a may include an opening 328 formed in the outer wall 322. For example, the first plate 323 may have a smaller area than the second plate 324 (e.g., a length and/or a width of the first plate 323 is smaller than that of the second plate 324), thereby partially exposing an inner space of the vapor chamber 320a.

Referring to FIGS. 5C and 5D, the heat pipe 330 may be positioned to close the opening 328 of the vapor chamber 320a. For example, the heat pipe 330 may be in contact with the first plate 323 while being positioned to overlap at least a portion of the second plate 324 in substantially the same plane as the first plate 323.

In various embodiments, the heat pipe 330 may close the opening 328 by being bonded to the vapor chamber 320a by bonding means such as solder. For example, after a solder paste is applied along a periphery of the opening 328, the heat pipe 330 may cover the opening 328, and the heat dissipation member 310 may be heated to a temperature equal to or higher than a melting point of the solder paste so that the opening 328 is sealed.

By forming the opening 328 in the vapor chamber 320a and sealing the opening 328 with the heat pipe 330, heat may be directly transferred to the heat pipe 330 without passing through the outer wall 322 of the vapor chamber 320a. Accordingly, the overall thermal resistance of the heat dissipation member 310 may be reduced.

Referring to FIG. 5E, a groove 324a may be formed at a corner portion of the second plate 324. For example, the groove 324a may be formed at a portion of a corner of the second plate 324 that is in contact with the heat pipe 330. The groove 324a may be a portion processed such that the corner portion of the second plate 324 at least partially has a concave shape.

Since the corner portion of the second plate 324 has a protruding shape, there may be insufficient space for applying solder paste for bonding the heat pipe 330 and the vapor chamber 320a, and it may be relatively difficult for molten solder to penetrate into a gap between the heat pipe 330 and the vapor chamber 320a due to capillary action. If the solder paste is incompletely applied to the corner portion of the second plate 324, or if penetration of molten solder is incomplete, there may be a risk that sealing of the vapor chamber 320a becomes incomplete. Since sealing of the vapor chamber 320a is required for operation of the vapor chamber 320a through repeated vaporization and condensation cycles of the PCM, if the vapor chamber 320a is not properly sealed, heat transfer performance of the vapor chamber 320a may deteriorate.

According to an embodiment of the disclosure, since the groove 324a is formed at a corner portion of the second plate 324 that is in contact with the heat pipe 330, the molten solder may easily penetrate into the corner portion through the concave groove 324a. Accordingly, an opening surface of the vapor chamber 320a may be easily sealed by the heat pipe 330, and deterioration of heat transfer performance of the vapor chamber 320a may be prevented and/or minimized.

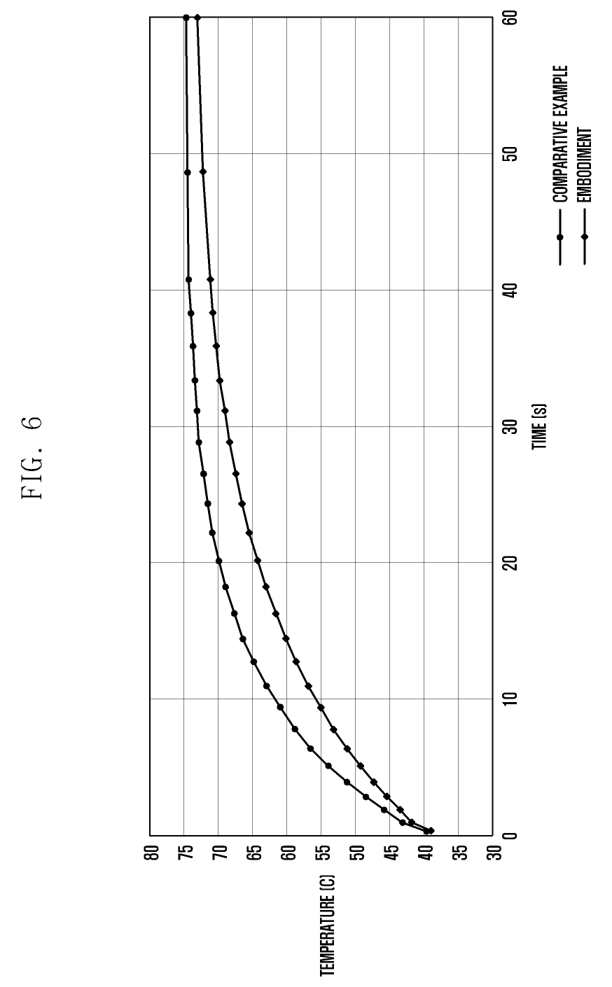

FIG. 6 is a graph illustrating temperatures of heat sources 303 during operation of electronic devices 300 according to an embodiment of the disclosure.

The comparative example of FIG. 6 is an electronic device configured to cool a heat source (e.g., a processor) by a heat pipe.

Referring to FIG. 6, it may be seen that in the electronic device according to the comparative example, the temperature of the heat source relatively rapidly increases after the start of operation. This may be because the thermal resistance of the heat pipe is relatively high, and thus a heat flux that may be released from the heat source is relatively low compared to the temperature of the heat source.

In contrast, since the heat dissipation member 310 of the electronic device 300 according to the embodiment of the disclosure has relatively lower thermal resistance than the heat pipe 330, sufficient heat flux may be obtained even at a lower temperature, and thus the temperature rise of the heat source 303 is relatively moderate. Accordingly, performance degradation of the heat source 303 such as the processor 303a due to throttling caused by temperature rise may be prevented and/or reduced, and damage due to overheating may also be prevented and/or reduced.

According to various embodiments of the disclosure, an electronic device 300 may include a substrate 302 including a heat source 303 disposed thereon 302, and a heat dissipation member 310 placed in contact with the heat source 303 and configured to dissipate heat of the heat source 303.

The heat dissipation member 310 may include a heat absorbing portion 320 including a vapor chamber 320a and configured to absorb heat from the heat source 303, a heat radiating portion 340 configured to release the heat absorbed by the heat absorbing portion 320, and a heat pipe 330 bonded to the vapor chamber 320a and configured to form a thermal circuit connecting the heat absorbing portion 320 and the heat radiating portion 340.

In various embodiments, the vapor chamber 320a and the heat pipe 330 may be bonded by solder.

In various embodiments, the heat dissipation member 310 may further include a solder layer 311 bonding the vapor chamber 320a and the heat pipe 330, the vapor chamber 320a may include a first surface 321 facing the heat pipe 330, the heat pipe 330 may include a second surface 331 facing the vapor chamber 320a, and the first surface 321 and the second surface 331 may be bonded to each other by the solder layer 311.

In various embodiments, at least one of the first surface 321 or the second surface 331 may have a contact angle of 15 degrees or less with respect to molten solder.

In various embodiments, the vapor chamber 320a may include a first plating layer formed on the first surface 321 and a second plating layer 331a formed on the second surface 331.

In various embodiments, at least one of the first surface 321 or the second surface 331 may be roughened.

In various embodiments, the heat pipe 330 may have a smaller thickness in a region overlapping the vapor chamber 320a compared to another region.

In various embodiments, the vapor chamber 320a may include an outer wall 322 partially surrounding an inner space of the vapor chamber 320a, the outer wall 322 may have an opening 328, and the heat pipe 330 may be positioned to close the opening 328.

In various embodiments, the outer wall 322 may include a first plate 323, a side wall 325 formed along an outer periphery of the first plate 323, and a second plate 324 positioned in parallel with the first plate 323 while being in contact with the side wall 325. The second plate 324 may have an area smaller than that of the first plate 323, and the heat pipe 330 may be positioned to overlap at least a portion of the first plate 323 in the same plane as the second plate 324 while being in contact with the second plate 324.

The second plate 324 may include a groove 324a formed at a corner portion of the second plate 324 that is in contact with the heat pipe 330.

According to various embodiments of the disclosure, a heat dissipation member 310 of the electronic device 300 having the heat source 303 may include a heat absorbing portion 320 including a vapor chamber 320a and configured to absorb heat from the heat source 303, a heat radiating portion 340 configured to release the heat absorbed by the heat absorbing portion 320, and a heat pipe 330 bonded to the vapor chamber 320a and configured to form a thermal circuit connecting the heat absorbing portion 320 and the heat radiating portion 340.

In various embodiments, the vapor chamber 320a and the heat pipe 330 may be bonded by solder.

In various embodiments, the heat dissipation member 310 may further include a solder layer 311 bonding the vapor chamber 320a and the heat pipe 330, the vapor chamber 320a may include a first surface 321 facing the heat pipe 330, the heat pipe 330 may include a second surface 331 facing the vapor chamber 320a, and the first surface 321 and the second surface 331 may be bonded to each other by the solder layer 311.

In various embodiments, at least one of the first surface 321 or the second surface 331 may have a contact angle of 15 degrees or less with respect to molten solder.

In various embodiments, the vapor chamber 320a may include a first plating layer formed on the first surface 321 and a second plating layer 331a formed on the second surface 331.

In various embodiments, at least one of the first surface 321 or the second surface 331 may be roughened.

In various embodiments, the heat pipe 330 may have a smaller thickness in a region overlapping the vapor chamber 320a compared to another region.

In various embodiments, the vapor chamber 320a may include an outer wall 322 partially surrounding an inner space of the vapor chamber 320a, the outer wall 322 may have an opening 328, and the heat pipe 330 may be positioned to close the opening 328.

In various embodiments, the outer wall 322 may include a first plate 323, a side wall 325 formed along an outer periphery of the first plate 323, and a second plate 324 positioned in parallel with the first plate 323 while being in contact with the side wall 325. The second plate 324 may have an area smaller than that of the first plate 323, and the heat pipe 330 may be positioned to overlap at least a portion of the first plate 323 in the same plane as the second plate 324 while being in contact with the second plate 324.

The second plate 324 may include a groove 324a formed at a corner portion of the second plate 324 that is in contact with the heat pipe 330.

It should be appreciated that the embodiments and the terms used therein are not intended to limit the technological features set forth herein to particular embodiments and the disclosure includes various changes, equivalents, or alternatives for a corresponding embodiment. With regard to the description of the drawings, similar reference numerals may be used to designate similar or relevant elements. A singular form of a noun corresponding to an item may include one or more of the items, unless the relevant context clearly indicates otherwise. As used herein, each of such phrases as "A or B," "at least one of A and B," “at least one of A or B,” "A, B, or C," "at least one of A, B, and C," and “at least one of A, B, or C,” may include any one or all possible combinations of the items enumerated together in a corresponding one of the phrases. Such terms as "a first," "a second," “the first,” and "the second" may be used to simply distinguish a corresponding element from another, and does not limit the elements in other aspect (e.g., importance or order). If an element (e.g., a first element) is referred to, with or without the term “operatively” or “communicatively”, as “coupled with/to” or “connected with/to” another element (e.g., a second element), it means that the element may be coupled/connected with/to the other element directly (e.g., wiredly), wirelessly, or via a third element.

As used in various embodiments of the disclosure, the term "module" may include a unit implemented in hardware, software, or firmware, and may be interchangeably used with other terms, for example, "logic," "logic block," "component," or "circuit". The “module” may be a single integrated component, or a minimum unit or part thereof, adapted to perform one or more functions. For example, according to an embodiment, the “module” may be implemented in the form of an application-specific integrated circuit (ASIC).

Various embodiments as set forth herein may be implemented as software (e.g., the program 140) including one or more instructions that are stored in a storage medium (e.g., the internal memory 136 or external memory 138) that is readable by a machine (e.g., the electronic device 101). For example, a processor (e.g., the processor 120) of the machine (e.g., the electronic device 101) may invoke at least one of the one or more stored instructions from the storage medium, and execute it. This allows the machine to be operated to perform at least one function according to the at least one instruction invoked. The one or more instructions may include a code generated by a complier or a code executable by an interpreter. The machine-readable storage medium may be provided in the form of a non-transitory storage medium. Herein, the term "non-transitory" simply means that the storage medium is a tangible device, and does not include a signal (e.g., an electromagnetic wave), but this term does not differentiate between where data is semi-permanently stored in the storage medium and where the data is temporarily stored in the storage medium.

According to an embodiment, methods according to various embodiments of the disclosure may be included and provided in a computer program product. The computer program product may be traded as a product between a seller and a buyer. The computer program product may be distributed in the form of a machine-readable storage medium (e.g., compact disc read only memory (CD-ROM)), or be distributed (e.g., downloaded or uploaded) online via an application store (e.g., Play Store^{TM}), or between two user devices (e.g., smart phones) directly. If distributed online, at least part of the computer program product may be temporarily generated or at least temporarily stored in the machine-readable storage medium, such as memory of the manufacturer's server, a server of the application store, or a relay server.

According to various embodiments, each element (e.g., a module or a program) of the above-described elements may include a single entity or multiple entities, and some of the multiple entities may be separately disposed in another element. According to various embodiments, one or more of the above-described elements or operations may be omitted, or one or more other elements or operations may be added. Alternatively or additionally, a plurality of elements (e.g., modules or programs) may be integrated into a single element. In such a case, according to various embodiments, the integrated element may still perform one or more functions of each of the plurality of elements in the same or similar manner as they are performed by a corresponding one of the plurality of elements before the integration. According to various embodiments, operations performed by the module, the program, or another element may be carried out sequentially, in parallel, repeatedly, or heuristically, or one or more of the operations may be executed in a different order or omitted, or one or more other operations may be added.

While the disclosure has been shown and described with reference to various embodiments thereof, it will be understood by those skilled in the art that various changes in form and details may be made therein without departing from the spirit and scope of the disclosure as defined by the appended claims and their equivalents.

What is claimed is:

1. An electronic device comprising:
a substrate comprising a heat source disposed on the substrate; and
a heat dissipation member placed in contact with the heat source and configured to dissipate heat of the heat source,
wherein the heat dissipation member comprises:
a heat absorbing portion comprising a vapor chamber and configured to absorb the heat from the heat source,
a heat radiating portion configured to release the heat absorbed by the heat absorbing portion, and
a heat pipe bonded to the vapor chamber and configured to form a thermal circuit connecting the heat absorbing portion and the heat radiating portion.

2. The electronic device of claim 1, wherein the vapor chamber and the heat pipe are bonded by soldering.

3. The electronic device of claim 1, further comprising:
a solder layer bonding the vapor chamber and the heat pipe,
wherein the vapor chamber comprises a first surface facing the heat pipe,
wherein the heat pipe comprises a second surface facing the vapor chamber, and
wherein the first surface and the second surface are bonded to each other by the solder layer.

4. The electronic device of claim 3, wherein at least one of the first surface or the second surface is roughened and has a contact angle of 15 degrees or less with respect to molten solder.

5. The electronic device of claim 3, wherein the vapor chamber comprises:
a first plating layer formed on the first surface; and
a second plating layer formed on the second surface.

6. The electronic device of claim 1, wherein the heat pipe has a smaller thickness in a region overlapping the vapor chamber compared to another region.

7. The electronic device of claim 1,
wherein the vapor chamber has an outer wall partially surrounding an inner space of the vapor chamber,
wherein the outer wall has an opening, and
wherein the heat pipe is positioned to close the opening.

8. The electronic device of claim 7,
wherein the outer wall comprises:
a first plate,
a side wall formed along an outer periphery of the first plate, and
a second plate positioned in parallel with the first plate while being in contact with the side wall,
wherein the second plate has an area smaller than that of the first plate and comprises a groove formed at a corner portion of the second plate that is in contact with the heat pipe, and
wherein the heat pipe is positioned to overlap at least a portion of the first plate in a same plane as the second plate while being in contact with the second plate.

9. A heat dissipation member of an electronic device having a heat source, the heat dissipation member comprising:
a heat absorbing portion comprising a vapor chamber and configured to absorb heat from the heat source;
a heat radiating portion configured to release the heat absorbed by the heat absorbing portion; and
a heat pipe bonded to the vapor chamber and configured to form a thermal circuit connecting the heat absorbing portion and the heat radiating portion.

10. The heat dissipation member of claim 9, further comprising:
a solder layer bonding the vapor chamber and the heat pipe,
wherein the vapor chamber comprises a first surface facing the heat pipe,
wherein the heat pipe comprises a second surface facing the vapor chamber, and
wherein the first surface and the second surface are bonded to each other by the solder layer.

11. The heat dissipation member of claim 10, wherein at least one of the first surface or the second surface is roughened and has a contact angle of 15 degrees or less with respect to molten solder.

12. The heat dissipation member of claim 10, wherein the vapor chamber comprises:
a first plating layer formed on the first surface;
and a second plating layer formed on the second surface.

13. The heat dissipation member of claim 9, wherein the heat pipe has a smaller thickness in a region overlapping the vapor chamber compared to another region.

14. The heat dissipation member of claim 9,
wherein the vapor chamber has an outer wall partially surrounding an inner space of the vapor chamber,
wherein the outer wall has an opening, and
wherein the heat pipe is positioned to close the opening.

15. The heat dissipation member of claim 14, wherein the outer wall comprises:
a first plate;
a side wall formed along an outer periphery of the first plate; and
a second plate positioned in parallel with the first plate while being in contact with the side wall,
wherein the second plate has an area smaller than that of the first plate, and comprises a groove formed at a corner portion of the second plate that is in contact with the heat pipe, and
wherein the heat pipe is positioned to overlap at least a portion of the first plate in a same plane as the second plate while being in contact with the second plate.

16. The heat dissipation member of claim 9, wherein the heat dissipation member placed in contact with the heat source and configured to dissipate heat of the heat source.

17. The heat dissipation member of claim 9, wherein the vapor chamber and the heat pipe are bonded by soldering.

18. The heat dissipation member of claim 9, wherein the vapor chamber and the heat pipe are joined by soldering.

19. The heat dissipation member of claim 10, wherein at least one surface of the first surface or the second surface is roughened.

20. The heat dissipation member of claim 15, wherein the second plate includes a groove formed at a corner portion of the second plate that is in contact with the heat pipe.
